(19) United States
(12) Patent Application Publication
(10) Pub. No.: US 2024/0355770 A1
(43) Pub. Date: Oct. 24, 2024

(54) SEMICONDUCTOR PACKAGE AND SEMICONDUCTOR DEVICE INCLUDING THE SAME

(71) Applicant: SAMSUNG ELECTRONICS CO., LTD., SUWON-SI (KR)

(72) Inventors: YOUNG-DEUK KIM, Suwon-si (KR); MI-NA CHOI, Suwon-si (KR); HEEJUNG HWANG, Suwon-si (KR)

(21) Appl. No.: 18/638,939

(22) Filed: Apr. 18, 2024

(30) Foreign Application Priority Data
Apr. 19, 2023 (KR) 10-2023-0051502

(51) Int. Cl. H01L 23/00; H01L 23/31; H01L 23/48

(52) U.S. Cl. CPC H01L 24/16; H01L 23/3107; H01L 23/481; H01L 24/05; H01L 24/32; H01L 24/73; H01L 2224/0401; H01L 2224/16145; H01L 2224/32145; H01L 2224/73204

(57) ABSTRACT

A semiconductor package includes a first semiconductor chip. A second semiconductor chip is disposed on the first semiconductor chip. A bump structure is disposed between the first semiconductor chip and the second semiconductor chip. The bump structure electrically connects the first semiconductor chip and the second semiconductor chip to each other. The bump structure includes a first bump pad and a second bump pad disposed on a same plane as each other, and a solder bump disposed between the first bump pad and the second bump pad. The solder bump abuts on a side of the first bump pad and a side of the second bump pad.

### CROSS-REFERENCE TO RELATED APPLICATION

This application claims priority under 35 U.S.C. § 119 to Korean Patent Application No. 10-2023-0051502, filed on Apr. 19, 2023 in the Korean Intellectual Property Office, the disclosure of which is incorporated by reference in its entirety herein.

### 1. TECHNICAL FIELD

The present disclosure relates to a semiconductor package. More particularly, the present disclosure relates to a semiconductor package and a semiconductor device including the same.

### 2. DISCUSSION OF RELATED ART

The demand for miniaturization, high capacity, and high performance of electronic products has increased along with the development of the information society. Thus, there has been an increased demand for semiconductor packages having an increased integration level and a higher speed. Semiconductor packages in which a plurality of semiconductor chips including TSV structures are stacked are being developed to provide an increased integration level and a higher speed.

For example, high bandwidth memory (HBM) which significantly increases the memory bandwidth by using high-speed serial links between semiconductor chips and packages is being developed. Unlike conventional memory, the HBM is configured in the form of a stack, allowing for a greater capacity within the PCB of the same area.

However, areas in which bump pads and bumps are placed within the HBM have a large amount of current flowing in a relatively small space. The thermal resistance is relatively large due to the low thermal conductivity of semiconductor chips and packages with very low thermal resistance. An issue with this high thermal resistance is that the gap between high-frequency signals or large bumps is very narrow, causing deformation of the material due to thermal expansion and contraction which can lead to cracks between semiconductor chips and packages. Thermal characteristics of the semiconductor package including the high-bandwidth memory can be increased by reducing the gap between chips in the high-bandwidth memory.

### SUMMARY

Embodiments of the present disclosure provide a semiconductor package with increased thermal characteristics.

According to another technical object, embodiments of the present disclosure provide a semiconductor device including the semiconductor package having the increased thermal characteristics.

According to an embodiment of the present disclosure, a semiconductor package includes a first semiconductor chip. A second semiconductor chip is disposed on the first semiconductor chip. A bump structure is disposed between the first semiconductor chip and the second semiconductor chip. The bump structure electrically connects the first semiconductor chip and the second semiconductor chip to each other. The bump structure includes a first bump pad and a second bump pad disposed on a same plane as each other, and a solder bump disposed between the first bump pad and the second bump pad. The solder bump abuts on a side of the first bump pad and a side of the second bump pad.

In an embodiment, the first bump pad and the second bump pad are spaced apart from each other by the solder bump.

In an embodiment, the first bump pad and the second bump pad may be symmetrically disposed on a plane relative to the solder bump. In an embodiment, the first bump pad and the second bump pad may have a same area as each other.

In an embodiment, at least a portion of the first bump pad and the second bump pad are disposed in direct contact with each other.

In an embodiment, the first bump pad and the second bump pad may have different areas on the plane.

In an embodiment, the ratio of a horizontal direction length of the solder bump to a horizontal direction length of the bump structure may be in a range of about 5/40 to about 15/50.

In an embodiment, the horizontal direction length of the bump structure may be in a range of about 40 μm to about 50 μm.

In an embodiment, the ratio of a gap between a top surface of the first semiconductor chip and a bottom surface of the second semiconductor chip to a horizontal direction length of the bump structure may be in a range of about 1/50 to about 5/40.

In an embodiment, the gap between the top surface of the first semiconductor chip and the bottom surface of the second semiconductor chip may be greater than 0 μm and less than or equal to about 5 μm.

In an embodiment, the bump structure is disposed in plurality between the first semiconductor chip and the second semiconductor chip. The ratio of a gap between a top surface of the first semiconductor chip and a bottom surface of the second semiconductor chip to a gap between centers of adjacent bump structures of the plurality of bump structures may be in a range of about 40/60 to about 60/40.

In an embodiment, the gap between the centers of the adjacent bump structures may be in a range of about 50 μm to 60 μm.

In an embodiment, the bump structure is disposed in plurality between the first semiconductor chip and the second semiconductor chip. A gap between opposing sidewalls of adjacent bump structures of the plurality of bump structures relative to a gap between the centers of the neighboring bump structures may be in a range of about 15/50 to about 25/40.

In an embodiment, the gap between the centers of the adjacent bump structures may be in a range of about 15 to about 25 μm.

In an embodiment, a dummy solder bump may be further disposed in at least a partial region between the first bump pad and a top of the first semiconductor chip, or between the second bump pad and a bottom of the second semiconductor chip.

In an embodiment, a first insulator is disposed on a top of the first semiconductor chip. The first insulator may abut on the first bump pad, the second bump pad, and the solder bump.

According to an embodiment of the present disclosure, a semiconductor package includes a base chip including a base TSV. A plurality of semiconductor chips is disposed on the base chip. The plurality of semiconductor chips are electrically connected to each other via a plurality of TSVs. An adhesive layer is disposed between the base chip and the plurality of semiconductor chips, and between each of the plurality of semiconductor chips. A sealant surrounds sides of the plurality of semiconductor chips and the adhesive layer. The plurality of semiconductor chips includes a bump structure disposed therebetween. The bump structure electrically connects the plurality of semiconductor chips to each other via the plurality of TSVs. The bump structure may include a first bump pad and a second bump pad disposed on a same plane as each other, and a solder bump disposed between the first bump pad and the second bump pad. The solder bump abuts on a side of the first bump pad and a side of the second bump pad.

In an embodiment, a gap between the plurality of semiconductor chips may be greater than 0 μm and less than or equal to about 5 μm.

According to an embodiment of the preset disclosure, a semiconductor device includes a package substrate. An interposer is mounted on the package substrate. At least one semiconductor package is mounted on the interposer. A processor chip is arranged side by side with the semiconductor package and mounted on the interposer. Each of the at least one semiconductor package includes a base chip connected to the interposer. A plurality of semiconductor chips is stacked on the base chip. At least one first bump structure is disposed between the plurality of semiconductor chips. The at least one first bump structure electrically connects the plurality of semiconductor chips to each other. Each of the at least one first bump structure may include a first bump pad and a second bump pad disposed on a same plane as each other, and a solder bump disposed between the first bump pad and the second bump pad. The solder bump abuts on sides of the first bump pad and the second bump pad.

In an embodiment, a second bump structure electrically connecting the semiconductor package and the interposer. The second bump structure may include a third bump pad and a fourth bump pad disposed on a same plane as each other, and a second solder bump disposed between the third bump pad and the fourth bump pad. The second solder bump abuts on a side of the third bump pad and a side of the fourth bump pad.

In an embodiment, a gap between the plurality of semiconductor chips in the semiconductor package may be greater than 0 μm and less than or equal to about 5 μm.

A semiconductor package according to an embodiment of the present disclosure includes a first bump pad, a second bump pad, and a solder bump disposed between semiconductor chips and disposed on the same plane to be horizontally bonded thereto, thereby providing a semiconductor package with increased thermal characteristics.

A semiconductor device according to an embodiment of the present disclosure provides a semiconductor device having the increased thermal characteristics.

### BRIEF DESCRIPTION OF THE DRAWINGS

FIG. 1 illustrates a cross-sectional view of a semiconductor package according to an embodiment of the present disclosure.

FIG. 2A to FIG. 2C illustrate an enlarged view of portion A of FIG. 1 according to embodiments of the present disclosure.

FIG. 3A to FIG. 3E illustrate a top plan view taken along line B-B′ of FIG. 2A according to embodiments of the present disclosure.

FIG. 4 is an enlarged view of region B of FIG. 1 according to an embodiment of the present disclosure.

FIG. 5A and FIG. 5B illustrate a semiconductor device including a semiconductor package according to embodiments of the present disclosure.

### DETAILED DESCRIPTION OF EMBODIMENTS

Hereinafter, embodiments of the present disclosure will be described in detail with reference to the accompanying drawings. As those skilled in the art would realize, embodiments of the present disclosure may be modified in various ways, all without departing from the spirit or scope of the present disclosure.

Accordingly, the drawings and description are to be regarded as illustrative in nature and not necessarily restrictive, and like reference numerals designate like constituent element throughout the specification.

The size and thickness of each configuration shown in the drawings may be arbitrarily shown for better understanding and ease of description and embodiments of the present disclosure are not necessarily limited thereto. In the drawings, the thickness of layers, films, panels, regions, etc., may be exaggerated for clarity. In the drawings, the thickness of layers and regions may be exaggerated for better understanding and ease of description.

It will be understood that when an element such as a layer, film, region, or substrate is referred to as being “on” another element, it can be directly on the other element or intervening elements may also be present. In contrast, when an element is referred to as being “directly on” another element, there are no intervening elements present. Further, in the specification, the word “on” or “above” means positioned on, above, or below the object portion and does not necessarily mean positioned on the upper side of the object portion based on a gravitational direction.

In addition, unless explicitly described to the contrary, the word “comprise”, and variations such as “comprises” or “comprising”, will be understood to imply the inclusion of stated elements but not the exclusion of any other elements.

Throughout the specification, the phrase “on a plane” means viewing the object portion from the top and the phrase “on a cross-section” means viewing a cross-section of which the object portion that vertically cut from the side.

Hereinafter, an embodiment of the present disclosure will be described in detail. As those skilled in the art would realize, the described embodiments may be modified in various ways, all without departing from the spirit or scope of the present disclosure.

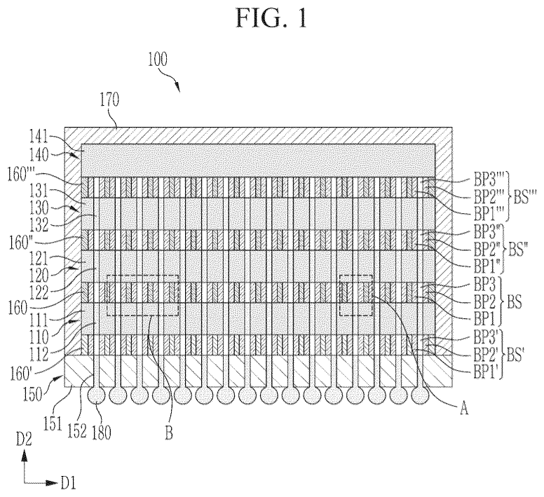

FIG. 1 illustrates a cross-sectional view of a semiconductor package 100 according to an embodiment of the present disclosure.

Referring to FIG. 1, a semiconductor package 100 illustrates stacked semiconductor chips. For example, the semiconductor package 100 may include a plurality of semiconductor chips 110, 120, 130, 140, a base chip 150, adhesive layers 160, 160′, 160″, 160″, and a sealant 170. For example, in an embodiment the semiconductor package 100 may be a high bandwidth memory (HBM) with a plurality of semiconductor chips 110, 120, 130, 140 stacked in the D2 direction. While FIG. 1 illustrates the plurality of semiconductor chips 110, 120, 130, 140 stacked in four layers, embodiments of the present disclosure are not necessarily limited thereto, and in some embodiments there may be four or more layers, eight or more layers, etc.

The plurality of semiconductor chips 110, 120, 130, 140 may be stacked with a plurality of semiconductor chips. For example, the plurality of semiconductor chips 110, 120, 130, 140 may include a plurality of semiconductor chips, such as a first semiconductor chip 110 and a second semiconductor chip 120. Hereinafter, the plurality of semiconductor chips 110, 120, 130, 140 are described with reference to the first semiconductor chip 110 for economy of description, and the elements of the second to fourth semiconductor chips 120, 130, 140 may correspond to those of the first semiconductor chip 110.

The first semiconductor chip 110 may include a first substrate part 111 and a first TSV 112. The first substrate part 111 may include a first substrate and a device layer. The first substrate may be a substrate including a semiconductor element. In an embodiment, the semiconductor element may include, for example, an element such as silicon (Si) or germanium (Ge). For example, the first substrate may include a compound semiconductor such as silicon carbide (SiC), galliumarsenide (GaAs), indiumarsenide (InAs), or indiumphosphide (InP). However, embodiments of the present disclosure are not necessarily limited thereto.

In an embodiment, the first substrate may have a silicon on insulator (SOI) structure. For example, the substrate may include a buried oxide layer (BOX layer). The first substrate may include a conductive region, such as a well doped with impurity, or a structure doped with impurity. The first substrate may include various device isolation structures, such as a shallow trench isolation (STI) structure.

The first device layer may include various types of devices depending on the type of chip. For example, in an embodiment the device layer may include FETs (Field Effect Transistors), such as planarFET and FinFETs, memories such as flash memory, dynamic random access memory (DRAM), static random access memory (SRAM), electrically erasable programmable read-only memory (EEPROM), phase-change random access memory (PRAM), and magnetoresistive random access memory (MRAM), ferroelectric random access memory (FeRAM), resistive random access memory (RRAM), logics such as AND, OR, and NOT, and various active and/or passive devices such as system LSI (Large Scale Integration), CMOS imaging sensor (CIS), and micro-electro-mechanical system (MEMS). In an embodiment, the device layer may be a volatile memory semiconductor chip such as DRAM or SRAM, or may include non-volatile memory devices such as PRAM, MRAM, FeRAM, or RRAM. More specifically, the first semiconductor chip 110 may be a high bandwidth memory (HBM) DRAM chip including DRAM devices in the first device layer.

The first TSV 112 is a structure for electrical connection between structures disposed on a top and a bottom of the first substrate part 111, and may extend continuously from the top surface to the bottom surface of the first substrate part 111 and penetrate the first substrate part 111. For example, in an embodiment the first TSV 112 may have a columnar shape. In an embodiment, the first TSV 112 may include various conductive materials such as copper (Cu), tungsten (W), nickel (Ni), ruthenium (Ru), or cobalt (Co). However, embodiments of the present disclosure are not necessarily limited thereto.

The first TSVs 112 may be arranged in a row along the direction D1 with reference to FIG. 1 at constant gaps or at different gaps. However, the first TSVs 112 may be disposed in various variations.

In an embodiment, the first TSV 112 may include a barrier film on an outer surface and a fill conductive layer on an inner surface. In an embodiment, the barrier film may include at least one material selected from Ti, TiN, Ta, TaN, Ru, Co, Mn, WN, Ni, and NiB. The fill conductive layer may include at least one material selected from Cu alloy, W, W alloy, Ni, Ru, and Co. The fill conductive layer may include, for example, a material such as Cu, CuSn, CuMg, CuNi, CuZn, CuPd, CuAu, CuRe, or CuW. However, embodiments of the present disclosure are not necessarily limited thereto.

In an embodiment, a via insulation layer may be interposed between the first substrate part 111 and the first TSV 112. In an embodiment, the via insulation layer may include, for example, an oxide film, a nitride film, a carbide film, a polymer, or a combination thereof. However, embodiments of the present disclosure are not necessarily limited thereto.

In an embodiment, the first semiconductor chip 110 and the second semiconductor chip 120 include a bump structure BS electrically connecting the first semiconductor chip 110 and the second semiconductor chip 120 to each other. For example, the bump structure BS is a member for electrically connecting the first TSV 112 of the first semiconductor chip 110 and a second TSV 122 of the second semiconductor chip 120 to each other.

The bump structure BS may include a first bump pad BP1, a second bump pad BP2, and a solder bump BP3. For example, the bump structure BS may include a first bump pad BP1 and a second bump pad BP2 disposed on the same plane as each other, and a solder bump BP3 disposed between the first bump pad BP1 and the second bump pad BP2 (e.g., in the first direction D1) and abutting on a side (e.g., an inner lateral side) of the first bump pad BP1 and a side (e.g., an inner lateral side) of the second bump pad BP2. The first bump pad BP1 and the second bump pad BP2 may be disposed in a horizontal direction, specifically in the direction D1, with the solder bump BP3 disposed between the first bump pad BP1 and the second bump pad BP2.

The first bump pad BP1 may be a member connected to (e.g., directly connected to) the second TSV 122 of the second semiconductor chip 120 stacked on the first semiconductor chip 110. The second bump pad BP2 may be a member connected to (e.g., directly connected to) the first TSV 112 of the first semiconductor chip 110.

In an embodiment, the first bump pad BP1 and the second bump pad BP2 may include a conductive material, for example, at least one compound selected from aluminum (AI), copper (Cu), nickel (Ni), tungsten (W), platinum (Pt), and gold (Au). However, embodiments of the present disclosure are not necessarily limited thereto. The first bump pad BP1 and the second bump pad BP2 include the conductive material, so that the first TSV 112 of the first semiconductor chip 110 and the second TSV 122 of the second semiconductor chip 120 may be electrically connected to each other.

The solder bump BP3 is a member for electrically connecting the first bump pad BP1 and the second bump pad BP2 to each other. The solder bump BP3 may be disposed between the first bump pad BP1 and the second bump pad BP2 in various forms. In an embodiment, the solder bump BP3 may include tin (Sn), indium (In), bismuth (Bi), antimony (Sb), copper (Cu), silver (Ag), zinc (Zn), lead (Pb), and/or alloys thereof. The solder bump BP3 may include a material such as, for example, Sn, Pb, Sn—Pb, Sn—Ag, Sn—Au, Sn—Cu, Sn—Bi, Sn—Zn, Sn—Ag—Cu, Sn—Ag—Bi, Sn—Ag—Zn, Sn—Cu—Bi, Sn—Cu—Zn, or Sn—Bi—Zn. However, embodiments of the present disclosure are not necessarily limited thereto.

In an embodiment, a diffusion barrier layer and/or an adhesive layer may be formed between the first bump pad BP1 and the second bump pad BP2 and the solder bump BP3, respectively. In an embodiment, the diffusion barrier layer may include, for example, nickel (Ni), cobalt (Co), copper (Cu), or a combination thereof. The adhesive layer may include, for example, nickel (Ni), copper (Cu), palladium (Pd), cobalt (Co), platinum (Pt), gold (Au), or a combination thereof. However, embodiments of the present disclosure are not necessarily limited thereto.

The plurality of semiconductor chips 110, 120, 130, 140 may be connected by bump structures BS, BS′, BS″ disposed in the horizontal direction. By including the bump structures BS, BS′, BS″, the semiconductor package 100 according to an embodiment of the present disclosure may reduce the distance between the plurality of semiconductor chips 110, 120, 130, 140 to reduce the thickness of the semiconductor package 100 and reduce the thermal resistance between the semiconductor chips.

The base chip 150 may be a member disposed at a bottommost surface of the semiconductor package 100. In an embodiment, the base chip 150 may have a size that is greater than or equal to the plurality of semiconductor chips 110, 120, 130, 140 disposed on top of the base chip 150. For example, in an embodiment the base chip 150 may have a cross-sectional area equal to a cross-sectional area of the plurality of semiconductor chips 110, 120, 130, 140 for electrically connecting and supporting the plurality of semiconductor chips 110, 120, 130, 140, or may have a cross-sectional area greater than a cross-sectional area of the plurality of semiconductor chips 110, 120, 130, 140.

The base chip 150 may include a base substrate part 151 and a base through silicon via (TSV) 152. For a detailed description for the base substrate part 151 and the base TSV 152, reference may be made to the first substrate part 111 and the first TSV 112 of the first semiconductor chip 110 described above.

The adhesive layers 160, 160′, 160″, 160′ may be interposed between the plurality of semiconductor chips 110, 120, 130, 140 (e.g., in the second direction D2) and between the base chip 150 and the first semiconductor chip 110 to wrap around the sides of the bump structure BS. For example, the adhesive layers 160, 160′, 160″, 160″ may surround the exterior sides (e.g., outer lateral sides) of the first bump pad BP1 and the second bump pad BP2. In an embodiment, the adhesive layers 160, 160′, 160″, 160′ may also protrude in the outward direction from the sides of the plurality of semiconductor chips 110, 120, 130, 140.

In an embodiment, the adhesive layers 160, 160′, 160″, 160′ may be formed of, for example, a non-conductive film (NCF). The NCF may serve as an adhesive to bond the plurality of semiconductor chips 110, 120, 130, 140 to each other or between the first semiconductor chip 110 and the base chip 150.

In an embodiment, the NCF may be utilized as an adhesive layer, for example, when bonding semiconductor chips by thermal compression bonding (TCB) in a semiconductor chip stacking process. For example, the NCF may be melted to have fluidity in the thermal compression bonding method.

The NCF may prevent the substrate from warping due to a difference in thermal expansion coefficient between the plurality of semiconductor chips 110, 120, 130, 140 or between the first semiconductor chip 110 and the base chip 150 during the bonding process. In an embodiment, the NCF may include, for example, an epoxy material.

The sealant 170 may surround the sides of the plurality of semiconductor chips 110, 120, 130, 140 and the adhesive layers 160, 160′, 160″, 160′″. In an embodiment, the sealant 170 may have a predetermined thickness and cover the top surface of the fourth semiconductor chip 140, which is disposed on the uppermost of the plurality of semiconductor chips 110, 120, 130, 140.

However, embodiments of the present disclosure are not necessarily limited thereto. For example, in an embodiment, the sealant 170 may not be formed on the top surface of the fourth semiconductor chip 140. Accordingly, the top surface of the fourth semiconductor chip 140 may be exposed to the outside. In an embodiment, the sealant 170 may include a thermosetting resin, such as an epoxy molding compound (EMC). However, embodiments of the present disclosure are not necessarily limited thereto.

In an embodiment, a bump 180 may be disposed below the base chip 150 (e.g., in the second direction D2). The bump 180 may be electrically connected to the base TSV 152 via a wire structure of the device layer in the base chip 150.

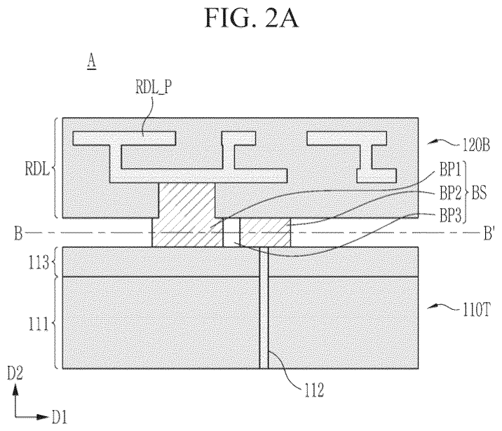

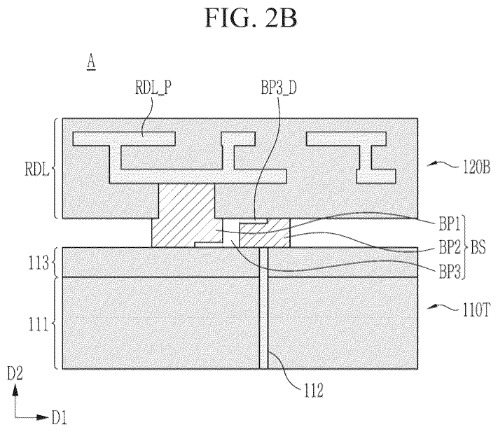

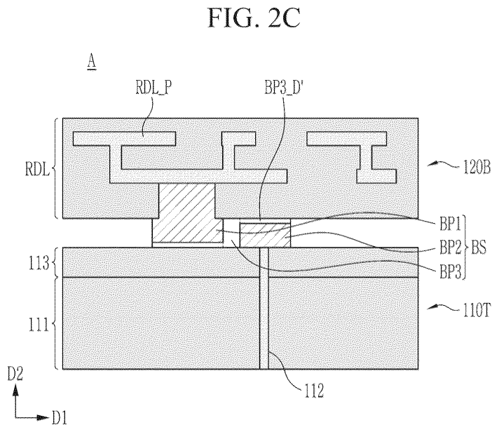

FIG. 2A to FIG. 2C illustrate an enlarged view of portion A of FIG. 1.

FIG. 2A is an enlarged view of portion A of FIG. 1. The bump structure BS may be disposed between a top surface 110T of the first semiconductor chip 110 and a bottom surface 120B of the second semiconductor chip 120. In an embodiment, the top surface 110T of the first semiconductor chip 110 may include, for example, the first substrate part 111 and a first insulator 113 disposed on the first substrate part 111 (e.g., disposed directly thereon in the second direction D2). A detailed description for the first substrate part 111 is as described above. In an embodiment, the first insulator 113 may include an insulating member including, for example, an oxide layer, a nitride layer, a carbonized layer, a polymer layer, or a combination thereof. However, embodiments of the present disclosure are not necessarily limited thereto. For example, the first insulator 113 may be an oxide layer including an oxide material. By including the first insulator 113, the first semiconductor chip 100 may maintain the stability of the semiconductor package by preventing the flow of leakage current in a relationship with the second semiconductor chip 120 disposed on the first semiconductor chip 110.

In an embodiment, the bottom surface 120B of the second semiconductor chip 120 may include a re-distribution layer (RDL). The RDL may include a re-distribution insulation film and a re-distribution structure disposed in the re-distribution insulation film. The re-distribution structure may include a re-distribution via interconnecting re-distribution patterns of multi-layer structure. In FIG. 2A, the RDL is illustrated as a predetermined pattern of a re-distribution layer pattern (RDL_P) including the re-distribution structure. However, embodiments of the present disclosure are not necessarily limited thereto and the RDL may vary from that shown in FIG. 2A. For example, the arrangement, the number of layers, and the number of the re-distribution structures may vary from an embodiment shown in FIG. 2A.

The bump structure BS may include the first bump pad BP1 and the second bump pad BP2 disposed on the same plane, and the solder bump BP3 disposed between the first bump pad BP1 and the second bump pad BP2 to bond the first bump pad BP1 and the second bump pad BP2 each other. As the first bump pad BP1, the second bump pad BP2, and the solder bump in the bump structure BS are disposed on the same plane as each other, specifically in a horizontal direction, such as the first direction D1, thereby reducing thermal resistance and the thickness of the semiconductor package 100 compared to conventional bump structures arranged in a vertical direction.

The solder bump BP3 may be disposed between the first bump pad BP1 and the second bump pad BP2 in a horizontal direction, such as the first direction D1. The solder bump BP3 may be disposed between the first bump pad BP1 and the second bump pad BP2 to electrically connect the first bump pad BP1 and the second bump pad BP2 to each other.

In an embodiment, the solder bump BP3 may bond the sides of the first bump pad BP1 and the second bump pad BP2 to each other, such as inner lateral sides of the first bump pad BP1 and the second bump pad BP2. Since the solder bump BP3 is not disposed on the top and bottom surfaces of the first bump pad BP1 and the second bump pad BP2, the bump structure BS may be disposed in a horizontal direction without bonding the first bump pad BP1 and the second bump pad BP2 directly to each other in a vertical direction, thereby reducing the thermal resistance and the thickness of the semiconductor package 100.

FIG. 2B and FIG. 2C illustrate an enlarged view of portion A of FIG. 1 according to an embodiment of the present disclosure.

Referring to FIG. 2B and FIG. 2C, the solder bump BP3 may further include a dummy solder bump BP3_D. The dummy solder bump BP3_D may be further disposed in at least a partial region between the first bump pad BP1 and the top of the first semiconductor chip 110, or between the second bump pad BP2 and the bottom of the second semiconductor chip 120. For example, the dummy solder bump BP3_D may be further disposed between the first bump pad BP1 and the top of the first semiconductor chip 110, or further disposed in at least a partial region between the second bump pad BP2 and the bottom of the second semiconductor chip 120, or disposed both between the first bump pad BP1 and the top of the first semiconductor chip 110 and in at least a partial region between the second bump pad BP2 and the bottom of the second semiconductor chip 120.

In an embodiment in which the solder bump BP3 is disposed between the first bump pad BP1 and the second bump pad BP2 to join the first bump pad BP1 and the second bump pad BP2, a portion of the solder bump BP3 of the dummy solder bump BP3_D may be spread and disposed on the top surface or bottom surface of the first bump pad BP1 or the second bump pad BP2.

FIG. 2B illustrates an embodiment in which the dummy solder bump BP3_D is disposed on a portion of the bottom surface of the first bump pad BP1 and a portion of the top surface of the second bump pad BP2. However, embodiments of the present disclosure are not necessarily limited thereto. For example, in an embodiment the dummy solder bump BP3_D may be disposed on the entire bottom surface of the first bump pad BP1 and/or the entire top surface of the second bump pad BP2.

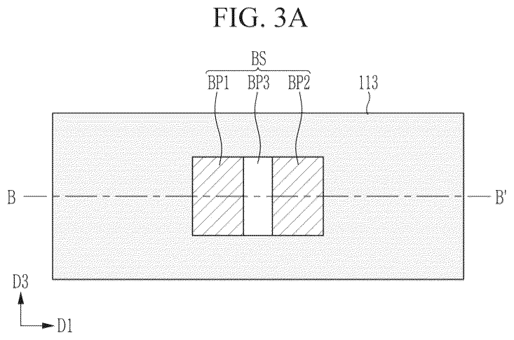

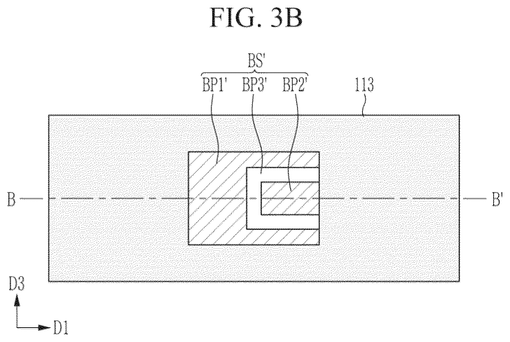

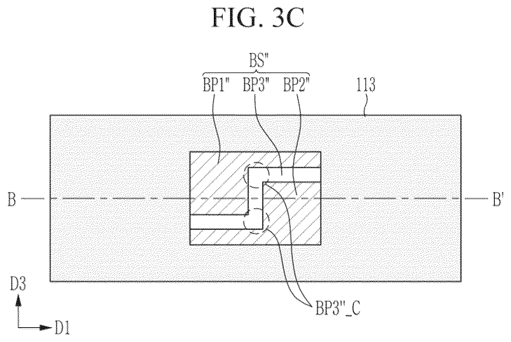

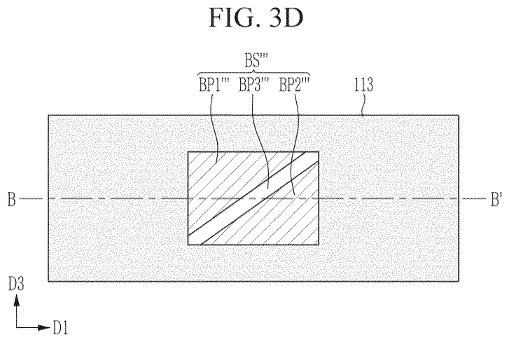

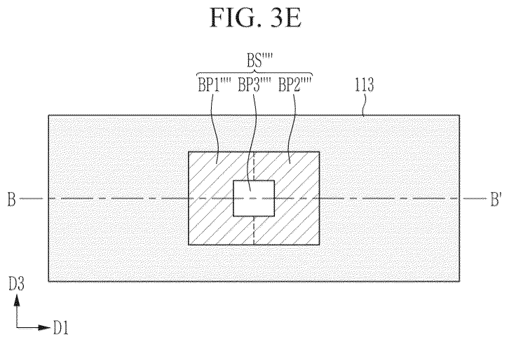

FIG. 3A to FIG. 3A illustrate a top plan view taken along line B-B′ of the bump structure BS of FIG. 2A.

Referring to FIG. 3A, in an embodiment, the solder bump BP3 may be disposed to space the first bump pad BP1 and the second bump pad BP2 apart from each other in a horizontal direction, such as the first direction D1. For example, the first bump pad BP1 and the second bump pad BP2 may be disposed separately, without directly contacting each other, by interposing the solder bump BP3 therebetween. More specifically, the solder bump BP3 may be disposed to extend in the direction D3 on the plane (e.g., in a horizontal direction perpendicular to the first direction D1).

The solder bump BP3 is shown in FIG. 3A as having a rectangular shape in a plan view. However, embodiments of the present disclosure are not necessarily limited thereto, and the solder bump BP3 may have various different shapes as a member capable of separating the first bump pad BP1 from the second bump pad BP2.

In an embodiment, the first bump pad BP1 and the second bump pad BP2 may be symmetrically disposed with same areas as each other on a plane relative to the solder bump BP3. FIG. 3A illustrates that the first bump pad BP1 and the second bump pad BP2 may have the same area on a plane.

Referring to FIG. 3B, a first bump pad BP1′ and a second bump pad BP2′ may have different areas on a plane relative to a solder bump BP3′. For example, in an embodiment, the first bump pad BP1′ has a larger area than the second bump pad BP2′. The first bump pad BP1′ and the second bump pad BP2′ may be disposed separately from each other. Although FIG. 3B illustrates that the first bump pad BP1′ has a larger area than the second bump pad BP2′, as a non-limiting example, in an embodiment the first bump pad BP1′ may have a smaller area than the second bump pad BP2′. The solder bump BP3′ may have a C-shape in a plan view and portions of the first bump pad BP1′ may extend an entire length of the bump structure BS' in the first direction D1. However, embodiments of the present disclosure are not necessarily limited thereto.

Referring to FIG. 3C, a solder bump BP3″ may be disposed with partial region extending to be unmatched from the direction D1. For example, the solder bump BP3″ may include a bending part BP3″_C bent at a predetermined angle between the first direction D1 to the third direction D3. While FIG. 3C illustrates the bending part BP3″_C having a 90° angle, this is a non-limiting example, and the predetermined angle may be an acute angle or an obtuse angle.

Referring to FIG. 3D, a solder bump BP3″ may be disposed extending to be unmatched from the direction D1 between the first and second bump pads BP1″, BP2″″ having symmetrical triangular shapes with a same area as each other. As shown in FIG. 3D the solder bump BP3″ may extend in a diagonal direction of approximately 45° between the first and third directions D1, D3. However, embodiments of the present disclosure are not necessarily limited thereto.

Referring to FIG. 3E, a solder bump BP3′″ may be disposed between a first bump pad BP1″ and a second bump pad BP2″. The solder bump BP3′″ maintains contact with (e.g., direct contact with) the partial region of the first bump pad BP1″ and the second bump pad BP2″, and the region other than the partial region may be electrically connected by the solder bump BP3″. For example, as shown in FIG. 3E, the solder bump BP3″″ may have a rectangular shape and may be completely surrounded (e.g., in the first and third directions D1, D3) by the first bump pad BP1″″ and the second bump pad BP2″ “. The first and second bump pads BP1”, BP2″″ may have C-shapes that are symmetrical to each other and the first and second bump pads BP1″ “, BP2” may have a same area as each other. At least a portion of the first and second bump pads BP1″, BP2″, such as the inner ends of the first and second bump pads BP1″, BP2″, may directly contact each other. In some embodiments, the first and second bump pads BP1″, BP2″″ may have at least portions directly contacting each other and the first and second bump pads BP1″, BP2″ may have different areas

The solder bumps BP3, BP3′, BP3″, BP3″, BP3′″ may be disposed in the bump structures BS, BS′, BS″, BS″, BS″ in various patterns to electrically connect the first bump pads BP3, BP1′, BP1″, BP1″, BP1″″ and the second bump pads BP2, BP2′, BP2″, BP2″, BP2″ in various forms.

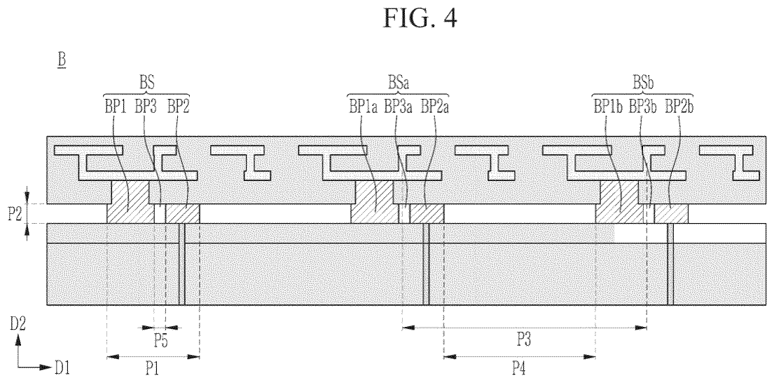

FIG. 4 is an enlarged view of B region of FIG. 1.

Referring to FIG. 4, in an embodiment, the ratio of the gap P2 (e.g., length in the second direction D2) between the top surface of the first semiconductor chip 110 and the bottom surface of the second semiconductor chip 120 to the horizontal direction thickness P1 (e.g., length in the first direction D1) of the bump structure BS may be in a range of about 1/50 to about 5/40. For example, the ratio may be in a range of about 1/25 to about 1/10. The horizontal direction length P1 of the bump structure BS means a transverse length in a cross-section of the bump structure BS, and the gap P2 between the top surface of the first semiconductor chip 110 and the bottom surface of the second semiconductor chip 120 means a longitudinal length in a cross-section of the bump structure BS, such as a height.

If the ratio is outside the above-described range, the gap between the semiconductor chips 110, 120 and the bump structures BS, BSa, BSb may be excessively narrow or wide, causing the semiconductor chips to bend due to thermal resistance. As the ratio satisfies the above-described range, the semiconductor chips 110, 120 can be appropriately spaced apart, thereby reducing the stacked height of the semiconductor chips to lower the thermal resistance. As said ratio satisfies the aforementioned range, the bump structures BS, BSa, BSb may be appropriately spaced apart, thereby reducing the failure rate due to contact between the bump structures BS, BSa, BSb.

In an embodiment, the horizontal direction length P1 of the bump structure BS may be in a range of about 40 to about 50 μm. For example, in an embodiment, the horizontal direction length P1 of the bump structure BS may be in a range of about 42 to about 48 μm. As the horizontal direction length P1 of the bump structure BS satisfies the above-described range, thereby reducing a package failure problem caused by heating between the bump structures BS that are spaced apart.

The height of the bump structure BS, which is the gap P2 between the top surface of the first semiconductor chip 110 and the bottom surface of the second semiconductor chip 120, may be in a range of greater than 0 μm to less than or equal to about 5 μm. For example, in an embodiment the height of the bump structure BS may be in a range of about 1 to about 4 μm. As the height of the bump structure BS satisfies the above-described range, thereby reducing the vertical thermal resistance by reducing the gap between the semiconductor chips 110, 120, 130, 140.

In an embodiment, the ratio of a horizontal direction length P5 (e.g., length in the first direction D1) of the solder bump BP3 to the horizontal direction length P1 (e.g., length in the first direction D1) of the bump structure BS may be in a range of about 5/40 to about 15/50. For example, the ratio may be in a range of about 8/40 to about 13/50.

In an embodiment, the horizontal direction length P5 of the bump structure BS may be in a range of about 5 to about 30 μm. For example, the horizontal length P5 of the bump structure BS may be in a range of about 8 to about 15 μm. As the horizontal direction length P5 of the bump structure BS satisfies the above-described range, thereby facilitating electrical connection between the first bump pad BP1 and the second bump pad BP2 in the bump structure BS.

In an embodiment, a plurality of bump structures BS may be disposed between the first semiconductor chip 110 and the second semiconductor chip 120, and the ratio of the gap P2 between the top surface of the first semiconductor chip 110 and the bottom surface of the second semiconductor chip 120 to the gap P3 between the centers of adjacent bump structures BS, BSa, BSb among the plurality of bump structures BS, BSa, BSb may be in a range of about 40/60 to about 60/40. For example, the ratio may be in a range of about 45/60 to about 50/40.

In an embodiment, the gap P3 between the centers of the neighboring bump structures BS, BSa, BSb may be in a range of about 50 μm to about 60 μm. For example, the gap may be in a range of about 52 μm to about 58 μm.

In an embodiment, in the bump structure BS, a ratio of a gap P4 (e.g., length in the first direction D1) between opposing sidewalls of the adjacent bump structure BS, BSa, BSb to the gap P3 (e.g., length in the first direction D1) between centers of the adjacent bump structures BS, BSa, BSb may be in a range of about 15/50 to about 25/40. For example, the ratio may be in a range of about 18/50 to about 22/40.

In an embodiment, the gap P4 between opposing sidewalls of the plurality of the adjacent bump structures BS, BSa, BSb may be in a range of about 15 to about 25 μm. For example, the gap may be in a range of about 18 to about 22 μm.

As the ratio of the gap satisfies the above-described range, thereby reducing the heating problem between the adjacent bump structures BS, BSa, BSb and the inferiority rate (e.g., failure rate) of the package due to the heating problem. If the ratio is outside the range described above, the inferiority rate (e.g., failure rate) of the package increases.

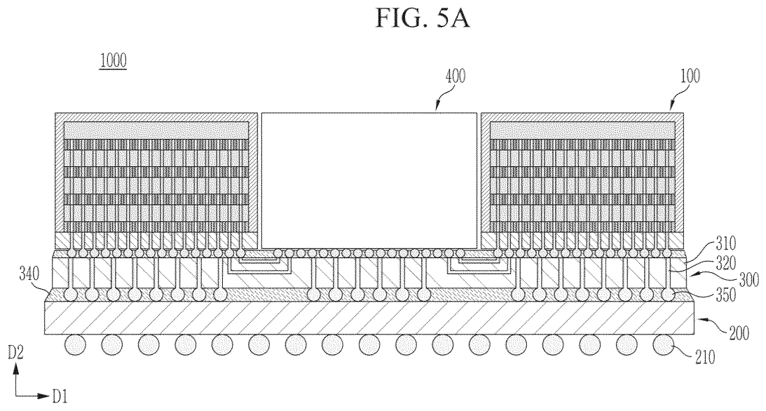

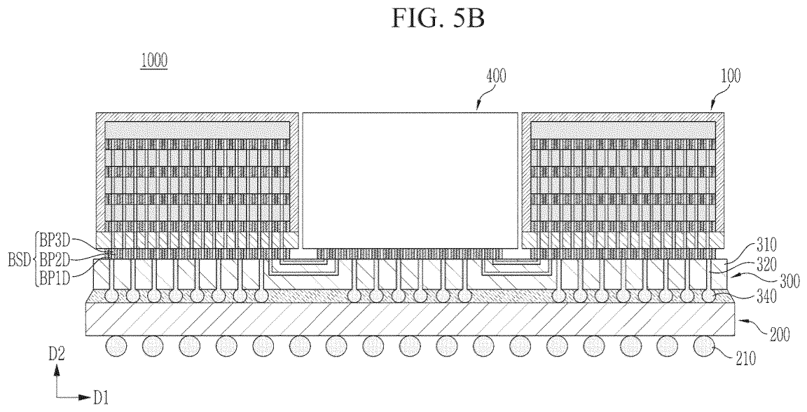

FIG. 5A and FIG. 5B illustrate a semiconductor device 1000 according to embodiments of the present disclosure.

Referring to FIG. 5A, the semiconductor device 1000 according to an embodiment of the present disclosure may include a semiconductor package 100, a package substrate 200, an interposer 300, a processor chip 400, and an outer sealant.

The semiconductor package 100 includes a first bump structure BS disposed between the plurality of semiconductor chips and electrically connecting the plurality of semiconductor chips. The first bump structure BS may include a first bump pad BP1 and a second bump pad BP2 disposed on the same plane, and a solder bump BP3 disposed between the first bump pad BP1 and the second bump pad BP2 and bonding sides of the first bump pad BP1 and the second bump pad BP2. While the first bump structure BS is illustrated as being disposed between all of the plurality of semiconductor chips disposed in the semiconductor package 100, this is a non-limiting example, and there may be a mixture of disposed and non-disposed layers between the plurality of semiconductor chips. A detailed description for the first bump structure BS may be found in reference to FIG. 1 to FIG. 4 described above.

The package substrate 200 may have an external connection terminal 210 such as a solder bump disposed outside (e.g., on a bottommost surface of the package substrate 200). The semiconductor device 1000 may be mounted on another external board and electrically connected to other devices via the external connection terminal 210.

The interposer 300 is disposed on the package substrate 200 and may be used for the purpose of converting or passing input electrical signals between the semiconductor package 100 and the processor chip 400 and the package substrate 200.

In an embodiment, the interposer 300 may include an interposer substrate 310, an interposer TSV 320, an interposer pad, an interposer wiring layer, and an interposer bump 350.

In an embodiment, the interposer substrate 310 may be formed from any of silicon, organic material, plastic, and glass substrate. However, embodiments of the present disclosure are not necessarily limited thereto. For example, in an embodiment in which the interposer substrate 310 of the interposer 300 is a silicon substrate, the interposer 300 may be used as a silicon interposer. In an embodiment in which the interposer substrate 310 of the interposer 300 is an organic material substrate, the interposer 300 may be used as a panel interposer. With respect to the silicon interposer and the panel interposer, the number of panel interposers manufactured from organic material quadrangle discs may be greater than the number of silicon interposers manufactured from one silicon wafer.

The interposer TSV 320 may extend from the top surface to the bottom surface of the interposer substrate 310 and penetrate the interposer substrate 310. The interposer TSV 320 may extend into the wiring layer 340. If the interposer substrate 310 is silicon, a through electrode 320 may be referred to as a TSV. Otherwise, the structure or material of the through electrode 320 may refer to that described for the first TSV 112 of the semiconductor package 100 of FIG. 1. In an embodiment, only a wiring layer may exist inside the interposer 300, and the interposer TSV 320 may not be included.

The interposer pad may be disposed on a top surface of substrate 310 to be electrically connected with the interposer TSV 320. The semiconductor package 100 and the processor chip 400 may be stacked on the interposer pad so that the semiconductor package 100 and the processor chip 400 and the package substrate 200 may be electrically connected. FIG. 5A illustrates that the interposer pad is filled in the interposer 300 and vertically bonded to the bump 180 of the semiconductor package 100.

In an embodiment, the interposer wiring layer 340 may have a single-layer or multi-layer wire structure. The interposer TSV 320 may penetrate a portion of the interposer wiring layer 340 and be electrically connected to wires of the interposer wiring layer 340. In an embodiment in which the interposer wiring layer 340 has two or more layers, wires from different layers may be connected via vertical contacts. The interposer wiring layer 340 may be disposed on the bottom surface of the interposer TSV 320 or may be disposed on top of the interposer TSV 320, so that the positional relationship between the interposer wiring layer 340 and the interposer TSV 320 may be relative.

In an embodiment, an interposer bump 350 may be disposed under the interposer 300 and electrically connected to the wire of the interposer wiring layer 340. The interposer bump 350 may be utilized when the interposer 300 is stacked and/or mounted on the package substrate 200, such as a printed circuit board (PCB). The interposer bump 350 may be connected to the interposer pad via a wire of the interposer wiring layer 340 and the interposer TSV 320. Among the interposer pads, the interposer pads utilized for power or ground may be integrated and connected to the interposer bumps 350, so that the number of the interposer pads may be greater than the number of the interposer bumps 350.

The processor chip 400 may be disposed side by side with the semiconductor package (e.g., in the first direction D1) and mounted on the interposer. In an embodiment, the processor chip 400 may be, for example, a GPU/CPU/SOC chip. The semiconductor device 1000 may be distinguished as a server-oriented semiconductor device or a mobile-oriented semiconductor device depending on the type of devices included inside the processor chip 400.

In an embodiment, the outer sealant may include a material such as epoxy molding compound. In an embodiment, the outer sealant may be formed with the sealant 170 of the semiconductor package 100. In an embodiment, the outer sealant may cover only the top surface of the processor chip 400 of the semiconductor package 100 and not the top surface of the semiconductor package 100.

Referring to FIG. 5B, in an embodiment, a second bump structure BSD may be further included between the bottom surface of the semiconductor package 100 and the top surface of the interposer 300 (e.g., in the second direction D2). For example, the second bump structure BSD electrically connecting the bottom surface of the semiconductor package 100 and the interposer 300 may be further included. In an embodiment, the second bump structure BSD may include a third bump pad BP1D and a fourth bump pad BP2D disposed on the same plane, and a second solder bump BP3D disposed between the third bump pad BP1D and the fourth bump pad BP2D and bonding a side of the third bump pad BP1D and a side of the fourth bump pad BP2D (e.g., inner lateral sides of the third and fourth bump pads BP1D, BP2D).

In an embodiment, the third bump pad BP1D may be connected to the interposer TSV 320 of the interposer 300 and may be arranged to protrude from the interposer 300 (e.g., in the second direction D2), and the fourth bump pad BP2D may be connected to (e.g., directly connected to) the base TSV 152 at the bottom of the semiconductor package 100 and may be arranged to protrude from the bottom of the semiconductor package 100 (e.g., in the second direction D2).

By reducing the height of the second bump structure BSD electrically connecting the semiconductor package 100 and the interposer 300, the thickness of the semiconductor device 1000 is reduced and provides desired heating characteristics between the bottom surface of the semiconductor package 100 and the interposer 300. A detailed description of the second bump structure BSD may be found in reference to the first bump structure BS described above without contradiction.

In an embodiment, the second bump structure BSD may be disposed not only between the semiconductor package 100 and the interposer 300, but also between the processor chip 400 and the interposer 300. As the second bump structure BSD is disposed between the semiconductor package 100 and the processor chip 400 and the interposer 300 (e.g., in the second direction D2). The semiconductor device 100 may have a flat height to reduce the inferiority rate (e.g., failure rate) of the semiconductor device 100 and control the thickness of the semiconductor device 100.

A manufacturing method of a semiconductor package according to an embodiment of the present disclosure is provided. The manufacturing method includes providing a first semiconductor chip provided with a first bump pad on a top surface. A semiconductor chip is stacked. A second semiconductor chip provided with a second bump pad is disposed on the same plane as the first bump pad on the bottom surface. The first bump pad and the second bump pad are bonded in a horizontal direction (e.g., the first direction D1) on the same plane relative to the solder bump. A detailed description of the first bump pad, the second bump pad, and the first semiconductor chip may be found in reference to FIG. 1A to FIG. 5B described above without contradiction.

In the providing of the first semiconductor chip with the first bump pad on a top surface, the first bump pad for electrical connection with a semiconductor chip being stacked, such as the second semiconductor chip, may be disposed to protrude on a top surface of the first semiconductor chip to be joined in a horizontal direction in the same plane as the second bump pad. The first bump pad may be disposed for lateral bonding in a horizontal direction with the second bump pad.

The providing of the second semiconductor chip provided with the second bump pad disposed on the same plane as the first bump pad on the bottom surface may include providing the second semiconductor chip so that the second bump pad is disposed on the same plane as the first bump pad.

In an embodiment, between the providing of the first semiconductor chip provided with the first bump pad on a top surface and the providing of the second semiconductor chip provided with the second bump pad disposed on the same plane as the first bump pad on the bottom surface, a solder bump is provided so that the first bump pad and the second bump pad are electrically connected to each other. A detailed description for the solder bump may be found in reference to FIG. 1 to FIG. 5B described above without contradiction.

In an embodiment, in the providing of the first semiconductor chip provided with the first bump pad on a top surface and the providing of the second semiconductor chip provided with the second bump pad disposed on the same line as the first bump pad on the bottom surface, the gap between the first semiconductor chip and the second semiconductor chip relative to a horizontal direction length of the bump structure including the first bump pad, the second bump pad, and the solder bump may be configured to be in a range of about 1/50 to about 5/40.

In an embodiment, in the providing of the first semiconductor chip provided with the first bump pad on a top surface and the providing of the second semiconductor chip provided with the second bump pad disposed on the same line as the first bump pad on the bottom surface, a gap between the top surface of the first semiconductor chip and the bottom surface of the second semiconductor chip may be configured to be in a range of greater than 0 μm to less than or equal to about 5 μm. In an embodiment, the horizontal direction length of the bump structure may be configured to be in a range of about 40 μm to about 50 μm.

In an embodiment, in the providing of the first semiconductor chip provided with the first bump pad on a top surface and the providing of the second semiconductor chip provided with the second bump pad disposed on the same line (e.g., a same plane in a horizontal direction) as the first bump pad on the bottom surface, the bump structures are disposed in plurality between the first semiconductor chip and the second semiconductor chip, the ratio of the gap between the top surface of the first semiconductor chip and the bottom surface of the second semiconductor chip to the gap between the centers of the neighboring bump structures may be configured to be in a range of about 40/60 to about 60/40. In an embodiment, the gap between opposing sidewalls of the adjacent bump structures may be configured to be in a range of about 15 to about 25 μm. A detailed description for the ratio and a numerical range may be found in reference to FIG. 1 to FIG. 5B without contradiction.

In an embodiment, in forming a bump structure by bonding the first bump pad and the second bump pad in a horizontal direction on the same plane relative to the solder bump, the bump structure may be formed by performing an electrolytic plating or reflow process on the first bump pad and the second bump pad by the solder bump. The bump structure is a structure including the first bump pad, the second bump pad, and the solder bump as described in FIG. 1 to FIG. 5B.

In an embodiment, the reflow process may be performed at a temperature range of, for example, about 220 to about 260° C. However, embodiments of the present disclosure are not necessarily limited thereto. By the reflow process, the solder bumps may be partially melted and bonded to the side of the first bump pad and the side of the second bump pad forming an intermetallic compound.

The present disclosure is not limited to the described embodiments and may be prepared in various forms, and it will be understood by a person of an ordinary skill in the art, to which the present disclosure pertains, that embodiments of the present disclosure may be implemented in other specific forms without modifying the technical spirit or essential feature of the present disclosure. Therefore, it should be understood that the embodiments described above are illustrative in terms of all aspects and embodiments of the present disclosure are not necessarily limited thereto.

What is claimed is:

1. A semiconductor package, comprising:
a first semiconductor chip;
a second semiconductor chip disposed on the first semiconductor chip; and
a bump structure disposed between the first semiconductor chip and the second semiconductor chip, the bump structure electrically connecting the first semiconductor chip and the second semiconductor chip to each other,
wherein the bump structure includes a first bump pad and a second bump pad disposed on a same plane as each other, and a solder bump disposed between the first bump pad and the second bump pad, the solder bump abutting on a side of the first bump pad and a side of the second bump pad.

2. The semiconductor package of claim 1, wherein:
the first bump pad and the second bump pad are spaced apart from each other by the solder bump.

3. The semiconductor package of claim 2, wherein:
the first bump pad and the second bump pad are symmetrically disposed on a plane relative to the solder bump; and
the first bump pad and the second bump pad have a same area as each other.

4. The semiconductor package of claim 1, wherein:
at least a portion of the first bump pad and the second bump pad are disposed in direct contact with each other.

5. The semiconductor package of claim 4, wherein:
the first bump pad and the second bump pad have different areas on the plane.

6. The semiconductor package of claim 1, wherein:
the ratio of a horizontal direction length of the solder bump to a horizontal direction length of the bump structure is in a range of about 5/40 to about 15/50.

7. The semiconductor package of claim 6, wherein:
the horizontal direction length of the bump structure is in a range of about 40 μm to about 50 μm.

8. The semiconductor package of claim 1, wherein:
the ratio of a gap between a top surface of the first semiconductor chip and a bottom surface of the second semiconductor chip to a horizontal direction length of the bump structure is in a range of about 1/50 to about 5/40.

9. The semiconductor package of claim 8, wherein:
the gap between the top surface of the first semiconductor chip and the bottom surface of the second semiconductor chip is greater than 0 μm and less than or equal to about 5 μm.

10. The semiconductor package of claim 1, wherein:
the bump structure is disposed in plurality between the first semiconductor chip and the second semiconductor chip; and
the ratio of a gap between a top surface of the first semiconductor chip and a bottom surface of the second semiconductor chip to a gap between centers of adjacent bump structures of the plurality of bump structures is in a range of about 40/60 to about 60/40.

11. The semiconductor package of claim 10, wherein:
the gap between the centers of the adjacent bump structures is in a range of about 50 μm to about 60 μm.

12. The semiconductor package of claim 1, wherein:
the bump structure is disposed in plurality between the first semiconductor chip and the second semiconductor chip; and
a gap between opposing sidewalls of adjacent bump structures of the plurality of bump structures relative to a gap between centers of the adjacent bump structures of the plurality of bump structures in in a range of about 15/50 to about 25/40.

13. The semiconductor package of claim 12, wherein:
the gap between the opposing sidewalls of the adjacent bump structures is in a range of about 15 μm to about 25 μm.

14. The semiconductor package of claim 1, wherein:
a dummy solder bump is further disposed in at least a partial region between the first bump pad and a top of the first semiconductor chip, or between the second bump pad and a bottom of the second semiconductor chip.

15. The semiconductor package of claim 1, wherein:
a first insulator is disposed on a top of the first semiconductor chip,
the first insulator abuts on the first bump pad, the second bump pad, and the solder bump.

16. A semiconductor package, comprising:
a base chip including a base TSV;
a plurality of semiconductor chips disposed on the base chip, the plurality of semiconductor chips are electrically connected to each other via a plurality of TSVs;
an adhesive layer disposed between the base chip and the plurality of semiconductor chips, and between each of the plurality of semiconductor chips; and
a sealant surrounding sides of the plurality of semiconductor chips and the adhesive layer,
wherein the plurality of semiconductor chips includes a bump structure disposed therebetween, the bump structure electrically connecting the plurality of semiconductor chips to each other via the plurality of TSVs,
the bump structure includes a first bump pad and a second bump pad disposed on a same plane as each other, and a solder bump disposed between the first bump pad and the second bump pad, the solder bump abutting on a side of the first bump pad and a side of the second bump pad.

17. The semiconductor package of claim 16, wherein:
a gap between the plurality of semiconductor chips is greater than 0 μm and less than or equal to about 5 μm.

18. A semiconductor device, comprising:
a package substrate;
an interposer mounted on the package substrate;
at least one semiconductor package mounted on the interposer; and
a processor chip arranged side by side with the semiconductor package and mounted on the interposer,
wherein each of the at least one semiconductor package comprises:
a base chip connected to the interposer;
a plurality of semiconductor chips stacked on the base chip; and
at least one first bump structure disposed between the plurality of semiconductor chips, the at least one first bump structure electrically connecting the plurality of semiconductor chips to each other,
each of the at least one first bump structure includes a first bump pad and a second bump pad disposed on a same plane as each other, and a solder bump disposed between the first bump pad and the second bump pad, the solder bump abutting on sides of the first bump pad and the second bump pad.

19. The semiconductor device of claim 18, further comprising:
a second bump structure electrically connecting the semiconductor package and the interposer,
wherein the second bump structure includes a third bump pad and a fourth bump pad disposed on a same plane as each other, and a second solder bump disposed between the third bump pad and the fourth bump pad, the second solder bump abutting on a side of the third bump pad and a side of the fourth bump pad.

20. The semiconductor device of claim 18, wherein:
a gap between the plurality of semiconductor chips in the semiconductor package is greater than 0 μm and less than or equal to about 5 μm.
